(19) United States
(12) Patent Application Publication
(10) Pub. No.: US 2007/0221269 A1
(43) Pub. Date: Sep. 27, 2007

(54) Photovoltaic conversion cell, photovoltaic conversion module, photovoltaic conversion panel, and photovoltaic conversion system

(75) Inventors: Satoshi Sakai, Kanagawa-ken (JP); Yasuyuki Kobayashi, Kanagawa-ken (JP); Saneyuki Goya, Kanagawa-ken (JP); Youji Nakano, Kanagawa-ken (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: MITSUBISHI HEAVY INDUSTRIES, LTD., Tokyo (JP)

(21) Appl. No.: 11/585,073

(22) Filed: Oct. 24, 2006

(30) Foreign Application Priority Data
Mar. 27, 2006 (JP) 2006-085931

(51) Int. Cl. H01L 31/00

(52) U.S. Cl. 136/252

(57) ABSTRACT

The efficiency of a thin film Si solar battery is improved. Between a back face electrode and a transparent conductive film provided on a front face side of the back face electrode, a refractive index adjustment layer is interposed made from a material that has a lower refractive index than that of the transparent conductive film. For example when the transparent conductive film is GZO, SiO₂ is interposed between the transparent conductive film and the back face electrode made from Ag. As a result light that penetrates into and is absorbed at the back face electrode is reduced, and the reflectivity of light at the back face electrode is improved.

### BACKGROUND OF THE INVENTION

1. Field of the Invention

The present invention relates to technology that increases the efficiency of photovoltaic conversion cells, photovoltaic conversion modules, photovoltaic conversion panels, and photovoltaic conversion systems.

This application is based on Japanese Patent Application No. 2006-00156, the content of which is incorporated herein by reference.

2. Description of Related Art

In Japanese Unexamined Patent Application, Publication No. Hei 5-110125, in regard to a photovoltaic element having a transparent conducting layer between a back face electrode provided on the opposite side to the light incidence face and a photovoltaic conversion layer comprising a semiconductor, there is disclosed a photovoltaic element characterized in that an element that changes electrical conductivity is included in the transparent conducting layer, and the added quantity of the element varies in the direction of film thickness. From paragraph number 0023 to paragraph number 0024 of this Japanese Unexamined Patent Application, Publication No. Hei 5-110125, there is the following description.

“Furthermore, as the interface with the semiconductor layer is approached, by monotonically reducing the added quantity of the element over, at least, a given thickness range, the long wavelength sensitivity of the photovoltaic element is increased, the short-circuit current is increased, and the photovoltaic conversion efficiency is increased.

In regard to this effect, by monotonically reducing the added quantity of the element as the interface with the back face electrode is approached, the refractive index of the conductive oxide monotonically decreases as the interface with the back face electrode is approached, reflection at the interface between the transparent electrode layer and the semiconductor layer is reduced, and it can be thought that the incidence of long wavelength light to the semiconductor layer is increased.”

In the Publication of Japanese Patent No. 2846508, in regard to a photovoltaic element having a transparent conducting layer, which comprises a compound of a plurality of elements, between a photoreflective back face electrode formed on the opposite side to the light incidence face, and a semiconductor layer that exhibits one conductivity type, there is disclosed a photovoltaic element characterized in that the compound that forms the aforementioned transparent conducting layer is a conductive oxide, and includes an area in which the oxygen composition ratio of the conductive oxide continuously varies in the direction of film thickness.

In regard to such thin film Si (Silicon) photovoltaic conversion cells as mentioned above, it is known that as a result of a rough interface resulting from a textured structure intended to scatter light, the photoabsorption at the metallic layer of the back face electrode increases. However, in regard to thin film Si photovoltaic conversion cells in which a-textured structure is not used, the light scattering is weak, and the short-circuit current decreases. Accordingly, further reinforcement of light reflection in back face electrodes configured by a transparent conductive film and a metallic layer is difficult, and it is difficult to increase the photovoltaic conversion efficiency.

The present invention has been accomplished in order to solve the above-mentioned problems, with objects of providing a photovoltaic conversion cell, a photovoltaic conversion module, a photovoltaic conversion panel, and a photovoltaic conversion system in which the photovoltaic conversion efficiency can be increased.

More specifically, the objects are to provide a photovoltaic conversion cell, a photovoltaic conversion module, a photovoltaic conversion panel, and a photovoltaic conversion system in which the photovoltaic conversion efficiency can be increased as a result of reducing the electromagnetic waves that penetrate and are absorbed by the back face electrode layer in a thin film Si solar battery (photovoltaic conversion cell).

### BRIEF SUMMARY OF THE INVENTION

The photovoltaic conversion cell according to the present invention comprises: a transparent substrate; a first photovoltaic conversion layer formed on a principal plane side of the transparent substrate that converts received light into electrical power; a back face electrode layer which is formed on a principal plane side, and is formed to a side of the first photovoltaic conversion layer opposite to a side in which outside light is incident on the first photovoltaic conversion layer; and a transparent layer which is formed between the first photovoltaic conversion layer and the back face electrode, and for which a side that is closer to the back face electrode layer has a smaller refractive index than a side that is distant from the back face electrode layer.

In the above-mentioned aspect of the invention, preferably the configuration is such that the transparent layer comprises: an upper portion transparent layer and a refractive index adjustment layer which is provided between the upper portion transparent layer and the back face electrode layer, and which has a smaller refractive index than the upper portion transparent layer.

In the above-mentioned configuration, preferably the upper portion transparent layer contains at least one of ZnO, ITO, and SnO₂. Preferably, the ZnO is doped with at least one of Ga, Si, Al, and B.

In the above-mentioned aspect of the invention, preferably the refractive index adjustment layer contains at least one of SiO₂, MgF₂, MgO, glass, Al₂O₃, Y₂O₃, CaF₂, LiF, and cavities.

In the above-mentioned aspect of the invention, in which the refractive index adjustment layer contains at least one of SiO₂, MgF₂, MgO, glass, Al₂O₃, Y₂O₃, CaF₂, LiF, and is provided with cavities, preferably, the refractive index adjustment layer contains a mixed phase between a first material and a second material; the first material is selected from among SiO₂, MgF₂, MgO, glass, Al₂O₃, Y₂O₃, CaF₂, and LiF; and the second material is selected from among ZnO, ITO, and SnO₂, the ZnO being doped with at least one of Ga, Si, Al, and B.

In the above-mentioned configuration, preferably the back face electrode layer contains at least one of Ag, Al, Cu, and Au.

In the above-mentioned configuration, preferably a thickness of the refractive index adjustment layer is at least 2 nanometers. More preferably, the thickness is at least 10 nanometers.

In the above-mentioned configuration, preferably the thickness of the refractive index adjustment layer is from 5 nanometers to 25 nanometers. More preferably, the thickness is from 10 nanometers to 20 nanometers.

In the above-mentioned aspect of the invention, preferably the transparent layer has a layer structure of at least three layers. Preferably, a refractive index of an upper side transparent layer, which is one of the layers within the layer structure, is greater than a refractive index of a lower side transparent layer, which is another one of the layers between the upper side transparent layer and the back face electrode layer.

In the above-mentioned invention, preferably the first photovoltaic conversion layer contains polycrystalline silicon, and furthermore, the second photovoltaic conversion layer containing amorphous silicon is included at the side opposite to the back face electrode layer with respect to the first photovoltaic conversion layer.

In the above-mentioned invention, in which the first photovoltaic conversion layer contains polycrystalline silicon, and the second photovoltaic conversion layer containing amorphous silicon is included at the side opposite to the back face electrode layer with respect to the first photovoltaic conversion layer, preferably the first photovoltaic conversion layer contains at least one of a compound of silicon and a group IV element other than silicon (for example, Ge), a CIS type compound, and a CIGS type compound.

In the-above-mentioned aspect of the invention, in which the first photovoltaic conversion layer contains polycrystalline silicon, and the second photovoltaic conversion layer containing amorphous silicon is included on the opposite side of the back face electrode layer with respect to the first photovoltaic conversion layer, preferably, a third photovoltaic conversion layer containing polycrystalline silicon is included between the first photovoltaic conversion layer and the second photovoltaic conversion layer.

In the above-mentioned aspect of the invention, preferably the first photovoltaic conversion layer contains polycrystalline silicon, and furthermore, a second photovoltaic conversion layer containing amorphous silicon is included on the opposite side of the back face electrode layer with respect to the first photovoltaic conversion layer, polycrystalline silicon is included between the first photovoltaic conversion layer and the second photovoltaic conversion layer, and a third photovoltaic conversion layer contains at least one of a compound between silicon and a group IV element other than silicon (for example, Ge), a CIS type compound, and a CIGS type compound.

In the present invention, preferably there is provided: a non-transparent substrate; a back face electrode layer formed on a principal plane side of the non-transparent substrate; a first photovoltaic conversion layer formed on the principal plane side, that converts received light into electrical power; and a transparent electrode layer which is formed on the principal plane side, and from a (side at which incident light is taken in; and a transparent layer which is formed between the back face electrode layer formed to a side of the first photovoltaic conversion layer opposite to a side at which outside light is incident on the first photovoltaic conversion layer, and the first photovoltaic conversion layer, and for which a side that is closer to the back face electrode layer has a smaller refractive index than a side that is distant from the back face electrode layer.

The photovoltaic conversion module of the present invention includes the above-mentioned photovoltaic conversion cells of the present invention, which are provided in plurality on one substrate and are integrated, and the integrated plurality of photovoltaic conversion cells are electrically connected.

The photovoltaic conversion panel of the present invention is provided with the above-mentioned photovoltaic conversion module of the present invention, and wiring that is at least electrically connected with the back face electrode layer, and supplies DC electrical power generated in the photovoltaic conversion module to an external load.

The photovoltaic conversion system of the present invention is provided with the above-mentioned photovoltaic conversion panel of the present invention, and an inverter that is electrically connected with the wiring, which converts DC electrical power provided to at least one of an external load and an electrical power system, into AC electrical power.

The photovoltaic conversion system of the present invention is provided with the above-mentioned photovoltaic conversion panel of the present invention, and a storage battery that is electrically connected with the wiring, which temporarily stores electrical power supplied to an external load.

The photovoltaic conversion cell, the photovoltaic conversion module, the photovoltaic conversion panel, and the photovoltaic conversion system of the present invention have an effect of increasing the photovoltaic conversion efficiency.

More specifically, the photovoltaic conversion cell, the photovoltaic conversion module, the photovoltaic conversion panel, and the photovoltaic conversion system of the present invention, as a result of a reduction in the amount of the electromagnetic waves that penetrate and are absorbed by the back face electrode layer in a thin film Si (Silicon) solar battery (photovoltaic conversion cell), have an effect of increasing the photovoltaic conversion efficiency.

### BRIEF DESCRIPTION OF THE SEVERAL VIEWS OF THE DRAWINGS

FIG. 1 is a cross-sectional view of the photovoltaic conversion cell according to a first embodiment of the present invention.

FIG. 2 is a cross-sectional view of the vicinity of the back face non-transparent electrode according to the photovoltaic conversion cell of FIG. 1.

FIG. 3 represents a calculation result of the electric field strength that penetrates into Ag when the material of the refractive index adjustment layer is changed.

FIG. 4 represents a calculation result of the integrated electric field strength.

FIG. 5 shows the dependency of the integrated electric field strength with respect to the film thickness of interposed media.

FIG. 6 shows the dependency of the integrated electric field strength with respect to the film thickness of interposed SiO₂.

FIG. 7 is a cross-sectional view of a photovoltaic conversion cell provided with a tandem cell construction.

FIG. 8 represents the layer structure of the tandem cell used for the calculations.

FIG. 9 shows the refractive index dependency of the refractive index adjustment layer with respect to the short-circuit current generated by a top cell layer by absorption of a p polarized component.

FIG. 10 shows the refractive index dependency of the refractive index adjustment layer with respect to the short-circuit current generated by a bottom cell layer by absorption of a p polarized component.

FIG. 11 shows the refractive index and film thickness dependency of the refractive index adjustment layer with respect to the short-circuit current generated by the bottom cell layer.

FIG. 12 is a cross-sectional view of a triple type photovoltaic conversion cell according to an embodiment of the present invention.

FIG. 13 is a schematic view explaining the configuration of a substrate type photovoltaic conversion cell to which the present invention has been applied.

FIG. 14 is a schematic view explaining another configuration of a substrate type photovoltaic conversion cell to which the present invention has been applied.

FIG. 15 is a schematic view explaining another configuration of a substrate type photovoltaic conversion cell to which the present invention has been applied.

FIG. 16 is a drawing explaining a configuration of a photovoltaic conversion module according to a second embodiment of the present invention.

FIG. 17 is a drawing explaining a configuration of a photovoltaic conversion panel according to a third embodiment of the present invention.

FIG. 18 is a perspective view explaining an external configuration of a photovoltaic conversion system according to a fourth embodiment of the present invention.

FIG. 19 is a block diagram explaining the configuration of the photovoltaic conversion system of FIG. 18.

FIG. 20 is a block diagram explaining a configuration of a photovoltaic conversion system according to a fifth embodiment of the present invention.

### DETAILED DESCRIPTION OF THE INVENTION

### First Embodiment

Hereinbelow, the best mode for implementing the photovoltaic conversion cell of a first embodiment according to the present invention is explained with reference to the drawings.

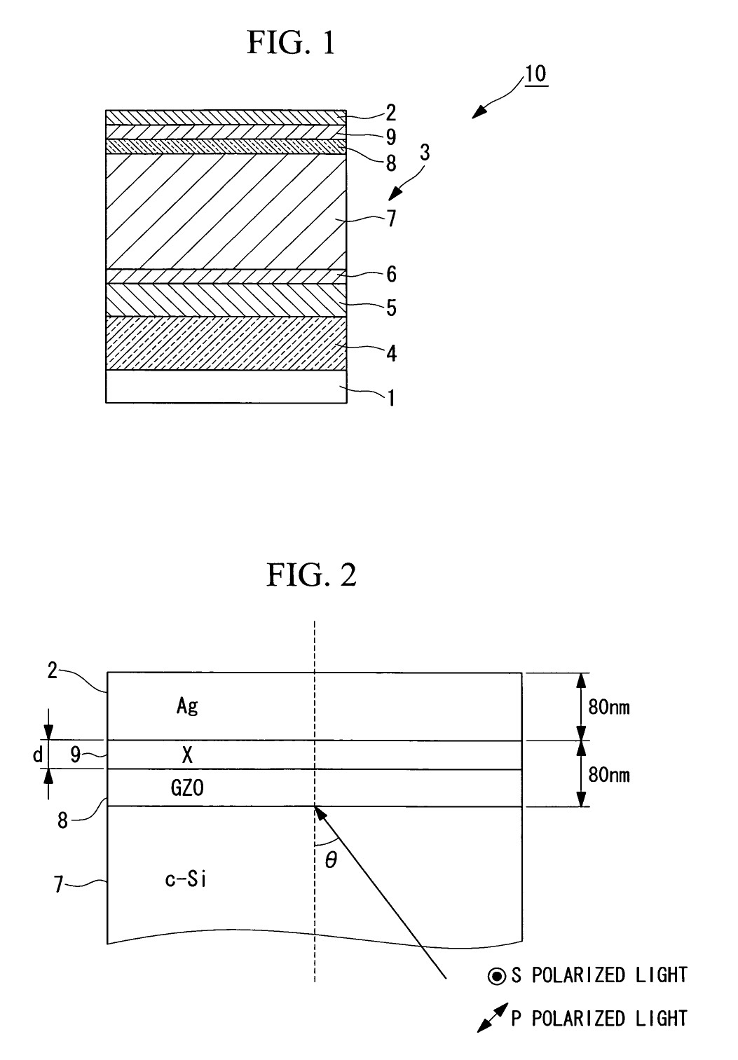

Referring to FIG. 1, a cross-sectional view of the photovoltaic conversion cell is shown. In regard to the photovoltaic conversion cell 10, a multilayered power generation layer 3 is formed between a light incident side glass substrate (transparent substrate) 1 and a back face non-transparent electrode (back face electrode layer) 2. The power generation layer 3 is formed as a six layered lamination structure comprising a first transparent (optically transparent) conductive layer 4, a top cell layer (second photovoltaic conversion layer) 5 which is a photovoltaic conversion layer, a middle layer 6 which is a transparent conductive film, a bottom cell layer (first photovoltaic conversion layer) 7 which is a photovoltaic conversion layer, a second transparent conductive film (transparent layer, upper portion transparent layer) 8, and a refractive index adjustment layer (transparent layer) 9.

The first transparent conductive film 4 is connected to the back face side of the glass substrate 1. The top cell layer 5 is connected to the back face side of the first transparent conductive film 4. The middle layer 6 is connected to the back face side of the top cell layer 5. The bottom cell layer 7 is connected to the back face side of the middle layer 6. The second transparent conductive film 8 is connected to the back face side of the bottom cell layer 7. The refractive index adjustment layer 9 is connected to the back face side of the second transparent conductive film 8. The back face non-transparent electrode 2 is connected to the back face side of the refractive index adjustment layer 9.

Here, in regard to the configuration elements such as the substrate, the film, and the layers, the face on which the light is incident is referred to as the front face, and the face from which the light is exiting is referred to as the back face.

Referring to FIG. 2, an enlarged cross-sectional view of a portion of the bottom cell layer 7, the second transparent conductive film 8, the refractive index adjustment layer 9, and the back face non-transparent electrode 2, is shown. In regard to the material of the layers in the vicinity of the back face non-transparent electrode 2 of the photovoltaic conversion cell 10, in the present embodiment the bottom cell layer 7 is c-Si (crystalline silicon) or μc-Si (microcrystalline silicon), the second transparent conductive film 8 is Ga-doped ZnO (GZO), and the back face non-transparent electrode 2 is Ag. In the present invention, a refractive index adjustment layer 9 is present between the second transparent conducting layer film 8 and the back face non-transparent electrode 2. The material X of the refractive index adjustment layer 9 is described below.

The top cell layer 5 and the bottom cell layer 7 may, as mentioned above, be deposited as c-Si (crystalline silicon) layers, μc-Si (microcrystalline silicon) layers, or a-Si (amorphous silicon) layers, and furthermore, they may be deposited as CIS type compound layers (a uniform layer comprising a composition of Cu, In, and Se) or CGIS type compound layers (a layer in which Ga has been further added to a uniform layer comprising a composition of Cu, In, and Se), and they are not particularly limited.

In the case in which the refractive index adjustment layer 9 is not present, the layer structure near the back face electrode of the solar battery (photovoltaic conversion cell 10) is, for example, Si power generation film/GZO/Ag. The optical reflectivity (R) of a GZO/Ag film deposited on a smooth glass substrate in the long wavelength region is sufficiently high (R=95% or more). That is to say, an explicit absorption loss in the GZO film and Ag interface is not observed. The reflectivity measurement configuration of the back face electrode on the glass substrate is an approximately perpendicular incidence condition. In this case, light polarization dependency does not occur.

On the other hand, in the case of oblique incidence, there is a need to consider the reflection characteristics of the two light polarization states, which are called s polarization and p polarization. In particular, in relation to p polarization, phenomena that are not possessed by s polarization, such as Brewster angle and surface plasmons at the dielectric/metallic interface are known.

The reflectivity of a metal is R=100% in an ideal metal, but in actual metals, such as Ag, approximately 98% is the maximum. Although the light is reflected at the dielectric/metallic interface, in reality, an electric field slightly penetrates into the metallic side. The penetration depth is on the order of a few tens of nm. The penetration depth is determined by the optical constant (refractive index n) of the dielectric substance, the optical constants (n, k) of the metal, the wavelength λ of the incident electromagnetic wave, and the angle of incidence θ. The electric field strength of the light that has penetrated into the metal exponentially decays with respect to the depth from the interface. Accordingly, it can be thought that the absorbance loss at the dielectric/metallic interface is determined by the penetration depth of the electric field.

The inventor of the present invention has changed the material of the refractive index adjustment layer 9 and has calculated the electric field strength distribution of the p-polarized light component in the Ag layer interior. In the calculations, as the material X of the refractive index adjustment layer 9, TiO₂ was used as a representative of a material with a higher refractive index than that of GZO, and SiO₂ was used as a representative of a material with a lower refractive index than that of GZO.

The film thickness of Ag was set to be 80 nm, which could be regarded as sufficiently bulky. The air on the back face side of Ag and the c-Si of the bottom cell layer 7 were assumed to be semi-infinite media. The angle of incidence of the incident light that is incident on the GZO interface from the c-Si was set to be θ. The thickness of the medium X that is interposed into the GZO/Ag interface was denoted as d. The sum of the thicknesses of the medium X and the GZO was set to be 80 nm. An OPTAS-FILM from Cybernet Corporation was used for calculations. The squares (E×E) of the electric field strengths in the Ag layer were calculated, the integral values (=the quantity in proportion to the absorbance loss in Ag) were calculated by using Excel from Microsoft Corporation, and the values were graphed. The present calculation is a flat film configuration calculation that considers the thin film multiple interference effect.

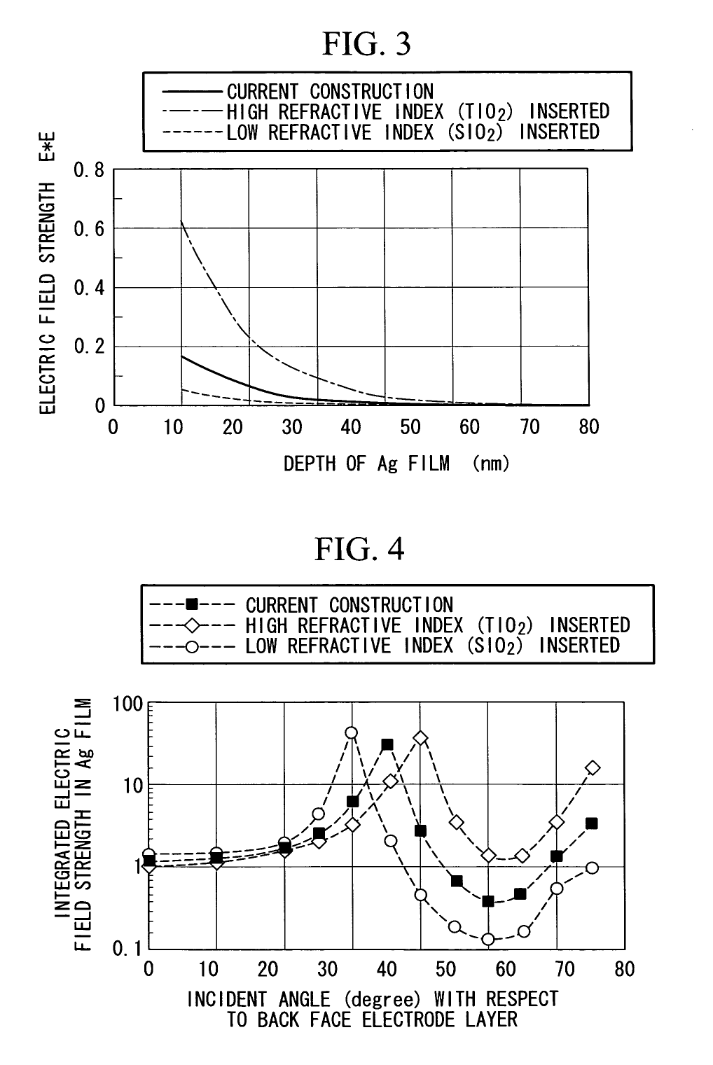

Hereinbelow, the calculation results are described using FIG. 3 to FIG. 6. In the explanation below, the “current construction” represents a construction in which the refractive index adjustment layer 9 is not present.

Referring to FIG. 3, the calculation results of the electric field strength distributions in the current construction, the TiO₂ interposed construction, and the SiO₂ interposed construction, are shown. These are calculation results are for an angle of incidence of 50°, a calculation light wavelength of 800 nm, and an interposed medium film thickness of 30 nm. From these results, it can be understood that, with respect to GZO, if a medium with a relatively higher refractive index than that of GZO is interposed, the electric field strength distribution becomes deeper and larger, and the absorbance loss at the Ag layer becomes larger (that is to say, the reflectivity decreases). Conversely, it can be understood that if a medium with a lower refractive index than that of GZO is interposed, the absorbance loss at the Ag layer can be reduced more than that in current constructions.

Referring to FIG. 4, the calculation results of the integrated electric field strengths are represented in a graph. These are calculation results for an interposed medium film thickness of 30 nm and a calculation light wavelength of 800 nm. The peak recognized from 30° to 40° is presumed to be the absorption enhancement as a result of surface plasmon resonance. If the angle of incidence exceeds 65°, the integrated electric field strength steeply decreases. This is presumed to be due to the total reflection of the Si/GZO interface.

The surface plasmon resonance phenomenon is not sufficiently observed if the smoothness and the angle of incidence are not strictly satisfied, and in an actual back face electrode (having corrugations of sizes on the order of the wavelengths of visible light) it is presumed that it is difficult for sharp absorption characteristics by the surface plasmon resonance to be observed. Consequently, although it is hypothetical, if FIG. 4 is viewed disregarding the peak from 30° to 40°, this can be interpreted to mean that the integrated electric field strength level is changing according to the refractive index of the material X of the refractive index adjustment layer 9 in the angle of incidence range of 45° to 65°. That is to say, by interposing a medium with a lower refractive index than that of GZO into the GZO/Ag interface, it can be said that there is a possibility that the absorbance loss resulting from Ag can be reduced.

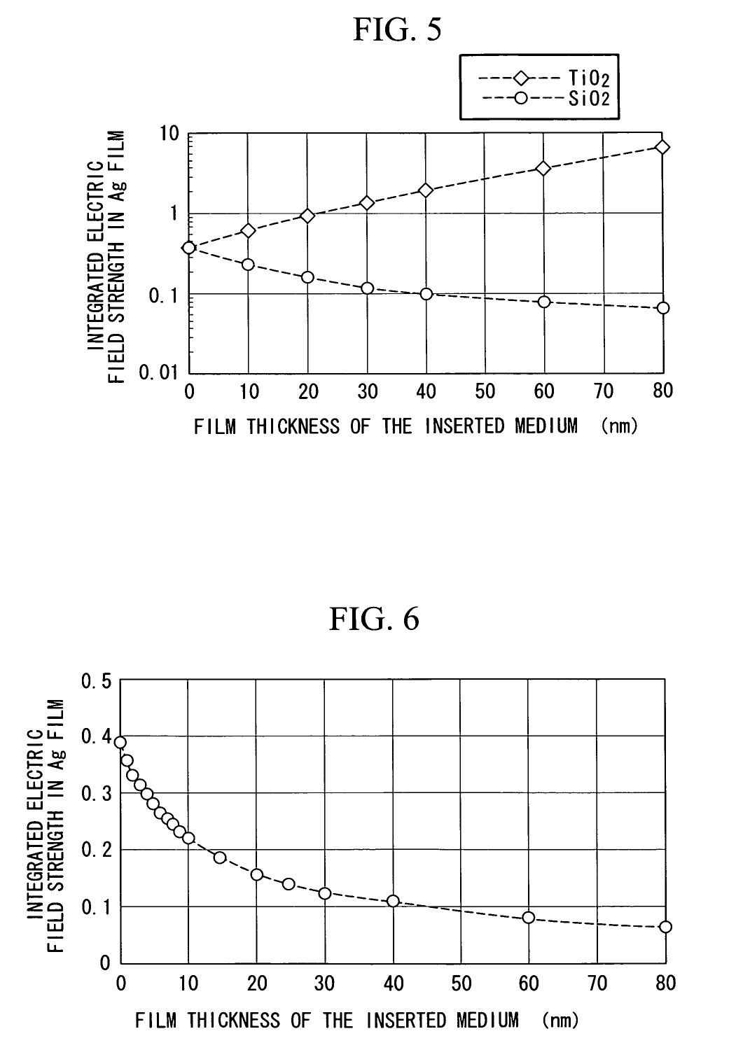

Referring to FIG. 5, the dependencies of the integrated electric field strength with respect to the film thickness of the interposed medium are shown. These are calculation results for an angle of incidence of 50° and a calculation light wavelength of 800 nm. The plot where the film thickness is zero represents the Si/GZO/Ag of the current construction, and the plot where the film thickness is 80 nm represents a Si/interposed medium X/Ag construction in FIG. 2. It is shown that as a result of the interposition of SiO₂, the integrated electric field strength can be decreased. There is a trend in that the thicker the SiO₂ film, the more the integrated electric field strength that penetrates into the Ag layer decreases.

Referring to FIG. 6, the dependency of the integrated electric field strength with respect to the film thickness of the interposed medium is shown for a case in which SiO₂ has been interposed in the same conditions as FIG. 5, and particularly in detail regarding the case in which the film is thin. According to this result, even with a film thickness is as small as 2 nm, the integrated electric field strength penetrating into the Ag layer is decreased. This is a result that is advantageous for the photovoltaic cell formation.

Next, the calculation of the effects of a refractive index adjustment layer in a photovoltaic conversion cell 10a furnished with the tandem cell structure is described.

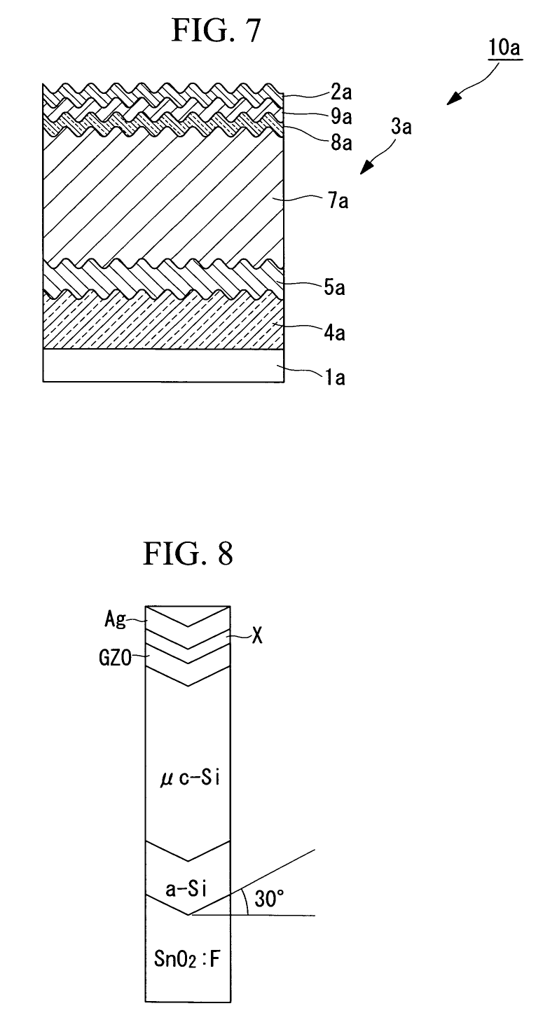

Referring to FIG. 7, a cross-sectional view of the photovoltaic conversion cell 10a furnished with a tandem cell structure is shown. On the back face side of the glass substrate 1a, a first transparent conductive film 4a is laminated. On the back face side of the first transparent conductive film 4a, a top cell layer 5a comprising a-Si (amorphous silicon) is laminated. On the back face side of the top cell layer 5a, a bottom cell layer 7a comprising μc-Si (microcrystalline silicon) is laminated. On the back face side of the bottom cell layer 7a, a second transparent conductive film 8a is laminated. On the back face side of the second transparent conductive film 8a, a refractive index adjustment layer 9a is laminated. On the back face side of the refractive index adjustment layer 9a, a back face non-transparent electrode 2a is laminated. The connecting faces of the layers laminated on the back face side of the glass substrate 1a are formed as textured structure faces.

Referring to FIG. 8, the tandem cell layer structure used for the calculations is shown. This layer structure is the same as the layer structure shown in FIG. 7. For the calculations, an electromagnetic wave analysis (the FDTD (Finite-Difference Time-Domain) method) was used. One period of the corrugations of the textured structure was taken out for the calculations, and the calculations were performed with a periodic boundary condition in which the left end thereof was the same as the right end. The corrugations of the textured structure were made to be corrugations that are 30 degrees to a plane that is parallel to the glass substrate (the glass substrate is not shown in FIG. 8). As the width (pitch) of one period of the corrugations of the textured structure, various conditions were specified, as mentioned below. The thickness of the glass substrate was assumed to be semi-infinite.

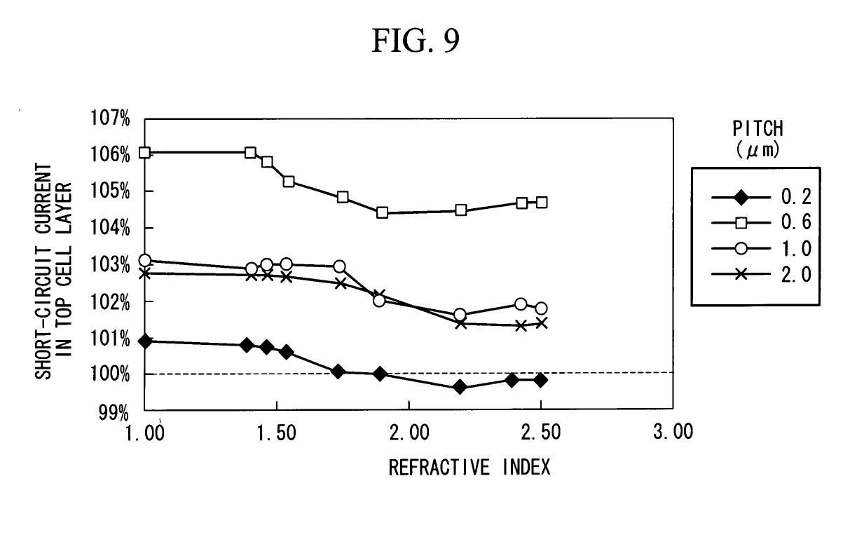

Referring to FIG. 9, the refractive index dependency of the refractive index adjustment layer 9a with respect to the short-circuit current generated by the p polarized component of the top cell layer 5a comprising a-Si is shown. The film thickness of the second transparent conductive film comprising GZO is 40 nm, and the thickness of the refractive index adjustment layer 9a is 40 nm. The short-circuit current in the case in which the pitch of one period of the corrugations is 0.2 μm, and the refractive index of the refractive index adjustment layer 9a is the same as GZO (n≈1.88) is taken to be 100%, as the standard. In any of these cases in which the pitch is 0.2 μm, 0.6 μm, 1.0 μm, and 2.0 μm, it can be deduced that the short-circuit increases as the refractive index of the refractive index adjustment layer 9a decreases.

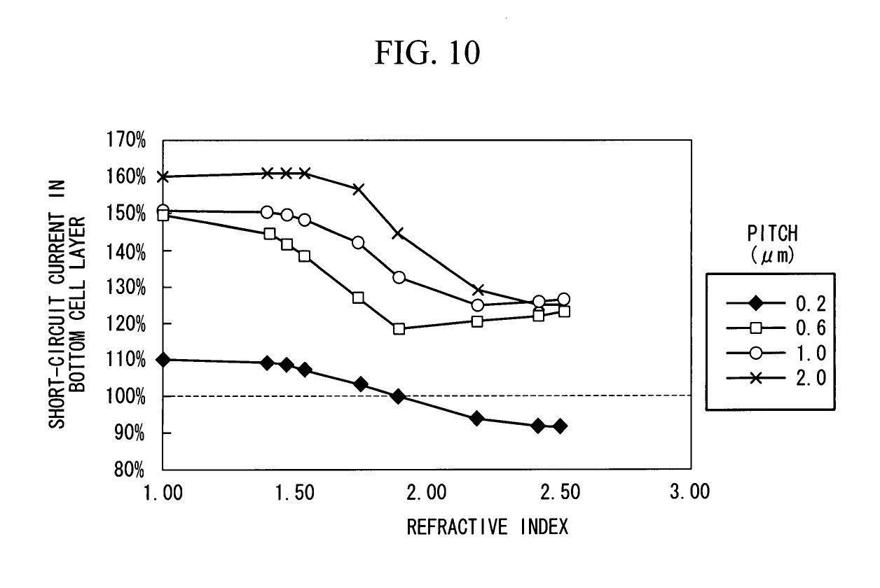

Referring to FIG. 10, the refractive index dependency of the refractive index adjustment layer 9a with respect to the short-circuit current generated by the p polarized component of the bottom cell layer 7a comprising μc-Si is shown. The film thickness of the second transparent conductive film comprising GZO is 40 nm, and the thickness of the refractive index adjustment layer 9a is 40 nm. The short-circuit current in the case in which the pitch of one period of the corrugations is 0.2 μm, and the refractive index of the refractive index adjustment layer 9a is the same as GZO (n≈1.88) is taken to be 100%, as the standard. In the same manner as in the case of the top cell layer 5a shown in FIG. 9, in any of the cases in which the pitch is 0.2 μm, 0.6 μm, 1.0 μm, and 2.0 μm, it can be deduced that the short-circuit increases as the refractive index of the refractive index adjustment layer 9a decreases.

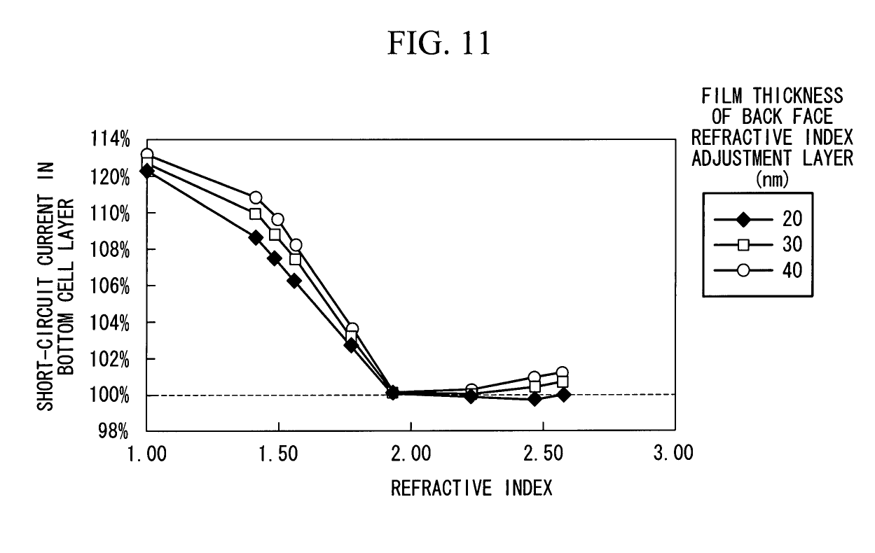

Referring to FIG. 11, the refractive index and film thickness dependency of the refractive index adjustment layer 9a with respect to the short-circuit current generated by the bottom cell layer 7a comprising μc-Si is shown. As the incident light, the average between the p polarized component and the s polarized component is used. The sum of the film thickness of the second transparent conductive film 8a comprising GZO, and the thickness of the refractive index adjustment layer 9a was set to be 80 nm. The pitch of one period of the corrugations is 0.6 μm. The short-circuit current in the case in which the refractive index of the refractive index adjustment layer 9a is the same as GZO (n≈1.88) is taken to be 100% as the standard. In any of these cases in which the film thickness of the refractive index adjustment layer 9a is 20 nm, 30 nm, and 40 nm, it can be deduced that in the case in which the refractive index of the refractive index adjustment layer 9a is smaller than GZO, the short-circuit current is larger.

From the calculation results shown in FIG. 3, FIG. 4, FIG. 5, FIG. 6, FIG. 9, FIG. 10, and FIG. 11, it is shown that as a result of a layer comprising a material with a smaller refractive index than the second transparent conductive film 8 or 8a being interposed between the second transparent conductive film 8 or 8a and the back face non-transparent electrode 2 or 2a, the strength of the electric field that penetrates and is absorbed by the back face non-transparent electrode 2 or 2a is suppressed, and as a result thereof, the power generation efficiency increases.

In contrast to the effects disclosed by Japanese Unexamined Patent Application, Publication No. Hei 5-110125, being obtained by the reduction of reflection at the interface between the transparent conducting layer and the semiconductor layer, the present invention is one in which the power generation efficiency is improved by the electromagnetic waves absorbed at the metallic layer of the back face electrode being reduced, and the principle is different.

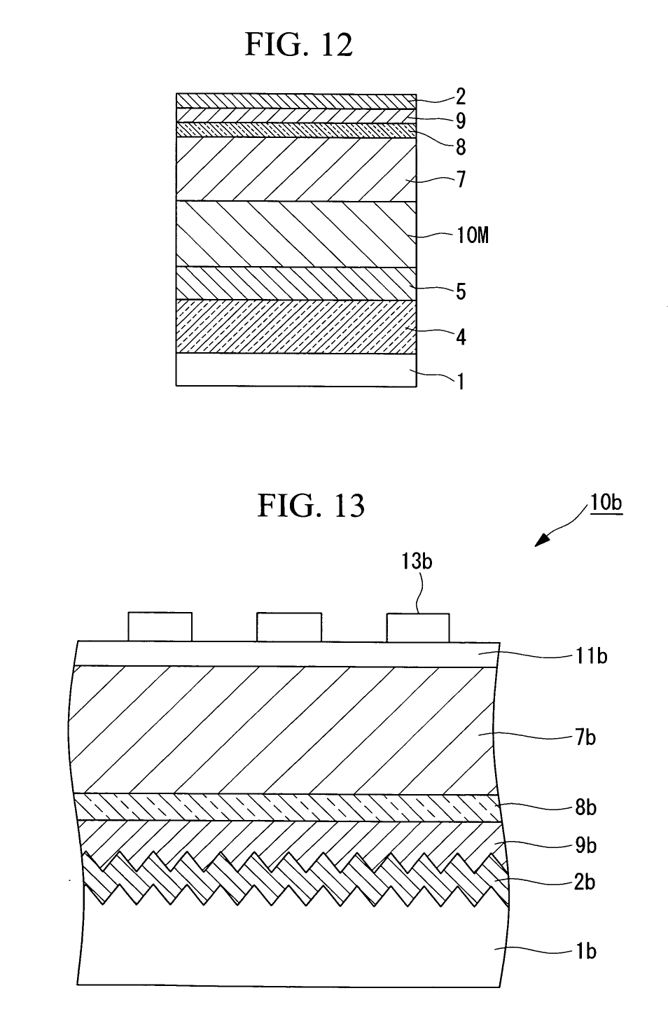

Referring to FIG. 12, another embodiment of the present invention is shown. Referring to FIG. 12, a glass substrate 1, a first transparent conducting layer 4, a top cell layer 5, a middle cell layer (a third photovoltaic conversion layer) 10M, a bottom cell layer 7, a second transparent conducting layer 8, a refractive index adjustment layer 9, and a back face non-transparent electrode 2 are sequentially laminated. The top cell layer 5 is a photovoltaic conversion layer containing amorphous silicon, the middle cell layer 10M is a photovoltaic conversion layer containing polycrystalline silicon (the case of microcrystalline silicon is also included), and the bottom cell layer 7 is a photovoltaic conversion layer containing polycrystalline silicon (the case of microcrystalline silicon is also included). A construction according to the present invention in which a refractive index adjustment layer 9 with a smaller refractive index than the second transparent conducting layer 8 is formed between the second transparent conducting layer 8 and the back face non-transparent electrode 2 is suitably used for such a triple type photovoltaic conversion cell.

Next, an evaluation experiment for the power generation characteristics of the photovoltaic conversion cell 10 according to the present embodiment is explained.

In regard to the photovoltaic conversion cell 10 used in the present experiment, the material X of the refractive index adjustment layer 9 uses a material comprising either SiO₂ or MgF₂. SiO₂ and MgF₂ are materials with lower refractive indexes than that of GZO. Furthermore, in regard to the refractive index adjustment layer 9, either SiO₂ or MgF₂ is formed with changes in the film thickness by vacuum vaporization under the conditions described below.

The formation of the refractive index adjustment layer 9 was performed by the vacuum vaporization method. The vaporization method used here is a technology commonly known as a general optical film formation method. In the case in which the material X of the refractive index adjustment layer 9 was SiO₂, SiO₂ glass was used as the target, and in the case in which the material X was MgF₂, a MgF₂ crystal was used as the target. The target and the substrate on which the film was deposited were disposed in a deposition apparatus, and following evacuation to a predetermined degree of vacuum, film deposition was performed by irradiating the target with an electron beam. In regard to the set temperature of the film production substrate, from room temperature to 300° C. is possible. The present embodiment was executed with a substrate temperature of 100° C. In regard to film thickness control, a typical quartz-crystal oscillator method was used. Deposition was performed by creating a calibration curve beforehand so that it becomes a predetermined film thickness.

In the present embodiment, although the vacuum evaporation method was used, the formation method of the refractive index adjustment layer 9 is not only restricted to the vacuum evaporation method, and the sputtering method is also suitable. The sputtering method is also a technology commonly known as a typical optical film formation method.

The power generation characteristics of the photovoltaic conversion cell 10 were evaluated by the short-circuit current density (JSC), the open circuit voltage (VOC), the fill factor (FF), and the power generation efficiency (Eff). Table 1 below shows the power generation characteristics of a photovoltaic conversion cell 10 that is a microcrystalline single cell that was experimentally produced based on the abovementioned evaporation conditions.

The power generation characteristics of the “current construction” in the Table represents the power generation characteristics of a microcrystalline single cell with a construction in which a refractive index adjustment layer 9 is not present, and it is the standard for evaluating the power generation characteristics of the microcrystalline single cells according to the present embodiment. The power generation characteristics of the “SiO₂ (film thickness 5 nm)” in the Table represents the power generation characteristics of a microcrystalline single cell in which the refractive index adjustment layer 9 is a layer wherein SiO₂ has been deposited to a film thickness of 5 nm, and are shown as relative values with the power generation characteristics relating to the “current construction” as the standard. In the same manner, the power generation characteristics of the ”MgF₂ (film thickness 5 nm)” represents the power generation characteristics of a microcrystalline single cell in which the refractive index adjustment layer 9 is a layer wherein MgF₂ has been deposited to a film thickness of 5 nm, and they are shown as relative values with the power generation characteristics relating to the “current construction” as the standard.

TABLE 1

| | Current | SiO₂ | MgF₂ |
|---|---|---|---|
| | Construction | (Film Thickness 5 nm) | (Film Thickness 5 nm) |
| Jsc | 1.00 | 1.02 | 1.02 |
| Voc | 1.00 | 1.00 | 1.01 |
| FF | 1.00 | 1.01 | 1.01 |
| Eff | 1.00 | 1.03 | 1.03 |

According to the power generation characteristics shown in Table 1, it can be understood that in regard to the refractive index adjustment layer 9, the power generation efficiency Eff in a microcrystalline single cell with a refractive index adjustment layer 9 of a SiO₂ layer of a film thickness of 5 nm or a microcrystalline single cell with a refractive index adjustment layer 9 of a MgF₂ layer of a film thickness of 5 nm, is improved over the power generation efficiency Eff of the microcrystalline single cell related to the current construction.

Table 2 below shows the power generation characteristics of a photovoltaic conversion cell 10 that is a tandem cell which has been similarly experimentally produced based on the evaporation conditions mentioned above.

The power generation characteristics of the “current construction” in the Table represents the power generation characteristics of a tandem cell with a construction in which a refractive index adjustment layer 9 is not present, and it is the standard for evaluating the power generation characteristics-of the tandem cells according to the present embodiment. The power generation characteristics of the “SiO₂ (film thickness 5 nm)” in the Table represents the power generation characteristics of a tandem cell in which the refractive index adjustment layer 9 is a layer wherein SiO₂ has been deposited to a film thickness of 5 nm and are shown as relative values with the power generation characteristics relating to the “current construction” as the standard. In the same manner, the power generation characteristics of the “MgF₂ (film thickness 5 nm)” represents the power generation characteristics of a tandem cell in which the refractive index adjustment layer 9 is a layer wherein MgF₂ has been deposited to a film thickness of 5 nm, and they are shown as relative values with the power generation characteristics relating to the “current construction” as the standard.

TABLE 2

| | Current | SiO₂ | MgF₂ |
|---|---|---|---|
| | Construction | (Film Thickness 5 nm) | (Film Thickness 5 nm) |
| Jsc | 1.00 | 1.03 | 1.03 |
| Voc | 1.00 | 0.99 | 1.00 |
| FF | 1.00 | 1.00 | 1.00 |
| Eff | 1.00 | 1.03 | 1.03 |

According to the power generation characteristics shown in Table 2, it can be understood that in regard to the refractive index adjustment layer 9, the power generation efficiency Eff in a tandem cell with the refractive index adjustment layer 9 of a SiO₂ layer of a film thickness of 5 nm or a tandem cell with the refractive index adjustment layer 9 of a MgF₂ layer of a film thickness of 5 nm, is improved over the power generation efficiency Eff of the tandem cell of the current construction.

Although it is not shown in Table 2, if the refractive index adjustment layer 9 is a SiO₂ layer and the film thickness exceeds 5 nm, since the non-conductivity of the refractive index adjustment layer 9 becomes high, the power generation efficiency Eff decreases. On the other hand, in the case in which the refractive index adjustment layer 9 is an MgF₂ layer, even if the film thickness exceeds 5 nm, the power generation efficiency Eff does not immediately decrease. In Table 3, the power generation characteristics in the case in which the MgF₂ layer film thickness is changed are shown.

Table 3 below shows the power generation characteristics of a photovoltaic conversion cell 10 that is a tandem cell that has been experimentally produced based on the evaporation conditions mentioned above.

The power generation characteristics of the “current construction” in the Table represents the power generation characteristics of a tandem cell with a construction in which a refractive index adjustment layer 9 is not present, and it is the standard for evaluating the power generation characteristics of the tandem cells according to the present embodiment. The power generation characteristics of the “MgF₂ (film thickness 5 nm)” in the Table represents the power generation characteristics of a tandem cell in which the refractive index adjustment layer 9 is a layer wherein MgF₂ has been deposited to a film thickness of 5 nm, and are shown as relative values with the power generation characteristics relating to the “current construction” as the standard. In the same manner, the power generation characteristics of the “MgF₂ (film thickness 10 nm)” represents the power generation characteristics of a tandem cell in which the refractive index adjustment layer 9 is a layer wherein MgF₂ has been deposited to a film thickness of 10 nm, and are shown as relative values with the power generation characteristics relating to the “current construction” as the standard. Below, in the same manner, the power generation characteristics of the “MgF₂ (film thickness 20 nm)” and the “MgF₂ (film thickness 30 nm)” represent the power generation characteristics of a tandem cell in which the refractive index adjustment layer 9 is a layer wherein MgF₂ has been deposited to a film thicknesses of 20 nm and 30 nm, and are shown as relative values with the power generation characteristics relating to the “current construction” as the standard.

TABLE 3

| | | MgF₂ | | MgF₂ | |
|---|---|---|---|---|---|
| | | (Film | MgF₂ (Film | (Film | MgF₂ (Film |
| | Current | Thickness | Thickness | Thickness | Thickness |
| | Construction | 5 nm) | 10 nm) | 20 nm) | 30 nm) |
| Jsc | 1.00 | 1.03 | 1.04 | 1.05 | 1.06 |
| Voc | 1.00 | 1.00 | 0.99 | 1.00 | 0.99 |
| FF | 1.00 | 1.00 | 1.01 | 1.04 | 0.95 |
| Eff | 1.00 | 1.03 | 1.05 | 1.09 | 1.00 |

According to the power generation characteristics shown in Table 3, it can be understood that in regard to the refractive index adjustment layer 9, the power generation efficiency Eff in a tandem cell with the refractive index adjustment layer 9 of a MgF₂ layer of a film thickness of 5 nm to a film thickness of 30 nm, is improved over the power generation efficiency Eff of the tandem cell related to the current construction.

Specifically, it is shown that if the film thickness of the refractive index adjustment layer 9 comprising a MgF₂ layer has a thickness within a range of 5 nanometers to 25 nanometers, the power generation efficiency Eff in the tandem cell is improved above the power generation efficiency Eff of the tandem cell related to the current construction. Furthermore, if the film thickness of the refractive index adjustment layer 9 comprising a MgF₂ layer has a thickness within a range of 10 nanometers to 20 nanometers, the improvement in the power generation efficiency Eff in the tandem cell is more noticeably exhibited.

FIG. 13 is a schematic view explaining the configuration of a substrate type photovoltaic conversion cell to which the present invention has been applied.

As mentioned above, the present invention may be applied to a superstrate type photovoltaic conversion cell, or it may be applied to a substrate type photovoltaic conversion cell, and it is not particularly limited.

For example, the photovoltaic conversion cell 10b shown in FIG. 13 is a substrate type photovoltaic conversion cell on which light is incident from the transparent electrode 11b side. The photovoltaic conversion cell 10b is furnished with a glass substrate 1b, a back face non-transparent electrode 2b, a refractive index adjustment layer 9b, a second transparent conductive film 8b, a photovoltaic conversion layer (first photovoltaic conversion layer) 7b, a transparent electrode 11b, and discharge electrodes 13b.

In regard to the transparent electrode 11b, as well as transmitting incident light towards the photovoltaic conversion layer 7b, it leads the electrical power generated in the photovoltaic conversion layer 7b to the discharge electrodes 13b. The discharge electrodes 13b lead the electrical power from the transparent electrode 11b to the outside.

Here, in regard to the configuration elements such as the substrate, the films, the layers, and the like, the face on which the light is incident is referred to as the front face, and the face from which the light exits is referred to as the back face.

The back face non-transparent electrode 2b is laminated on the front face side of the glass substrate 1b. The refractive index adjustment layer 9b is laminated on the front face side of the back face non-transparent electrode 2b. The second transparent conductive film 8b is laminated on the front face side of the refractive index adjustment layer 9b. The photovoltaic conversion layer 7b is laminated on the front face side of the second transparent conductive film 8b. The transparent electrode 11b is laminated on the front face side of the photovoltaic conversion layer 7b. The discharge electrodes 13b are formed on the front face side of the transparent electrode 11b.

A textured structure is formed on the front face of the glass substrate 1b, that is, the front face is formed as a textured structure face. The connection face between the back face non-transparent electrode 2b laminated on the front face side of the glass substrate 1b and the refractive index adjustment layer 9b laminated on the front face side of the back face non-transparent electrode 2b conforms, as a textured structure face, to the front face of the glass substrate 1b.

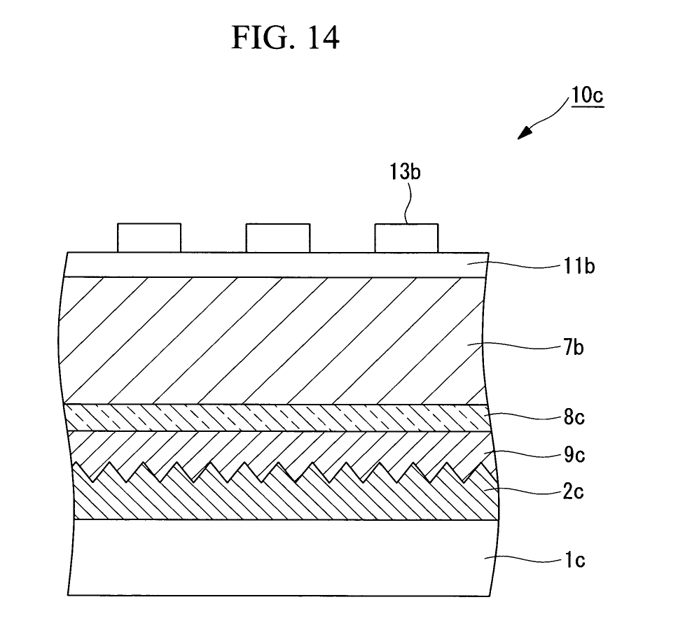

FIG. 14 is a schematic view explaining another configuration of a substrate type photovoltaic conversion cell to which the present invention has been applied.

The photovoltaic conversion cell 10c shown in FIG. 14 is a substrate type photovoltaic conversion cell of a separate configuration to the photovoltaic conversion cell 10b shown in FIG. 13. The photovoltaic conversion cell 10c is furnished with a glass substrate 1c, a back face non-transparent electrode 2c, a refractive index adjustment layer 9c, a second transparent conductive film 8c, a photovoltaic conversion layer 7b, a transparent electrode 11b, and discharge electrodes 13b.

Here, in regard to the configuration elements such as the substrate, the films, the layers, and the like, the face on which the light is incident is referred to as the front face, and the face from which the light exits is referred to as the back face.

The back face non-transparent electrode 2c is laminated on the front face side of the glass substrate 1c. The refractive index adjustment layer 9c is laminated on the front face side of the back face non-transparent electrode 2c. The second transparent conductive film 8c is laminated on the front face side of the refractive index adjustment layer 9c. The photovoltaic conversion layer 7b is laminated on the front face side of the second transparent conductive film 8c. The transparent electrode 11b is laminated on the front face side of the photovoltaic conversion layer 7b. The discharge electrodes 13b are formed on the front face side of the transparent electrode 11b.

A textured structure is formed on the front face of the back face non-transparent electrode 2c, that is, the front face is formed as a textured structure face. The connection face between the back face non-transparent electrode 2c and the refractive index adjustment layer 9c laminated on the front face side of the back face non-transparent electrode 2c conforms, as a textured structure face, to the front face of the back face non-transparent electrode 2c.

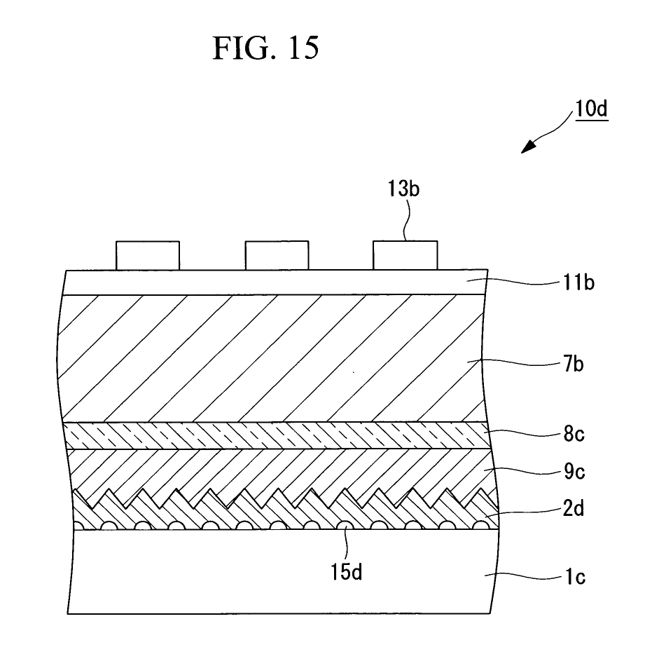

FIG. 15 is a schematic view explaining another configuration of a substrate type photovoltaic conversion cell to which the present invention has been applied.

The photovoltaic conversion cell 10d shown in FIG. 15 is a substrate type photovoltaic conversion cell of another separate configuration to the photovoltaic conversion cell 10b shown in FIG. 13. The photovoltaic conversion cell 10d is furnished with a glass substrate 1c, structure bodies 15d, a back face non-transparent electrode 2d, a refractive index adjustment layer 9c, a second transparent conductive film 8c, a photovoltaic conversion layer 7b, a transparent electrode 11b, and discharge electrodes 13b.

The structure bodies 15d are arranged between the glass substrate 1c and the back face non-transparent electrode 2d, and are formed in a textured structure form.

Here, in regard to the configuration elements such as the substrate, the films, the layers, and the like, the face on which the light is incident is referred to as the front face, and the face from which the light exits is referred to as the back face.

The back face non-transparent electrode 2d is laminated on the front face side of the glass substrate 1c. The refractive index adjustment layer 9c is laminated on the front face side of the back face non-transparent electrode 2d. The second transparent conductive film 8c is laminated on the front face side of the refractive index adjustment layer 9c. The photovoltaic conversion layer 7b is laminated on the front face side of the second transparent conductive film 8c. The transparent electrode 11b is laminated on the front face side of the photovoltaic conversion layer 7b. The discharge electrodes 13b are formed on the front face side of the transparent electrode 11b.

The structured bodies 15d are arranged on the front face of the glass substrate 1c, and the connection face between the back face non-transparent electrode 2d that is laminated on the front face side of the glass substrate 1c and the refractive index adjustment layer 9c laminated on the front face side of the back face non-transparent electrode 2d conforms, as a textured structure face, to the structured bodies 15d.

### Second Embodiment

Hereinbelow, a photovoltaic conversion module furnished with the photovoltaic conversion cell of a second embodiment according to the present invention is explained.

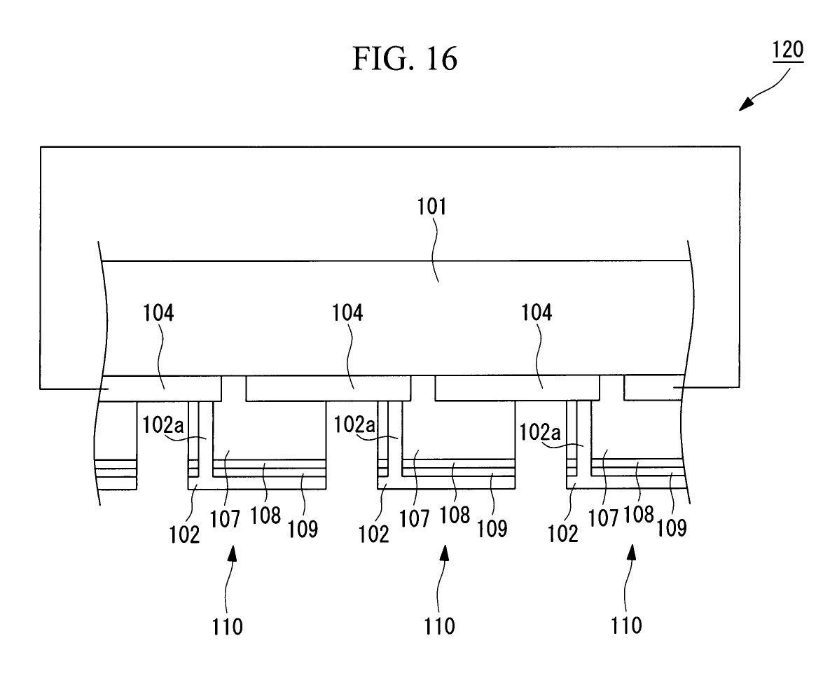

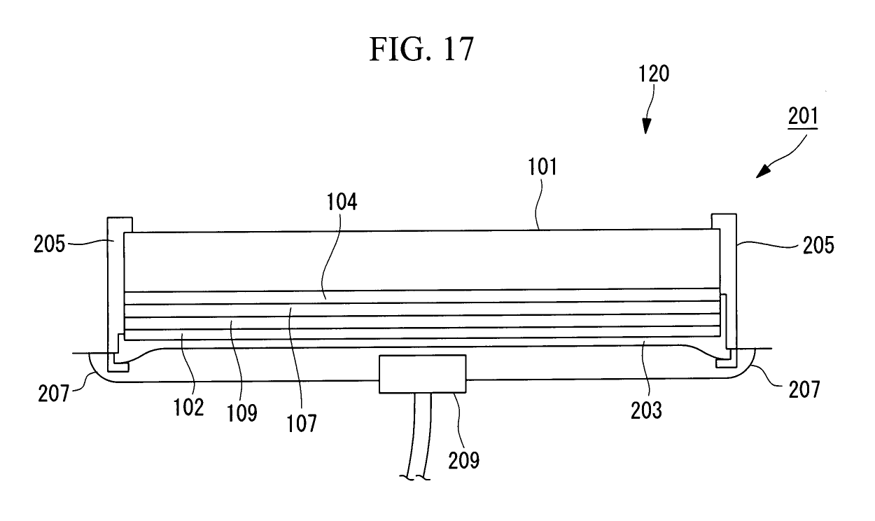

FIG. 16 is a drawing explaining the configuration of the photovoltaic conversion module in the present embodiment.

The photovoltaic conversion module 120 is, as shown in FIG. 16, multiply provided with a plurality of photovoltaic conversion cells 110 on a sheet of glass substrate 101, and is one in which the plurality of photovoltaic conversion cells 110 are electrically connected in series. The photovoltaic conversion cells 110 are furnished with a first transparent conductive film 104, a photovoltaic conversion layer (first photovoltaic conversion layer) 107, a second transparent conductive film (transparent layer, upper portion transparent layer) 108, a refractive index adjustment layer (transparent layer) 109, and a back face non-transparent electrode (back face electrode layer) 102.

The first transparent conductive films 104 are conductive layers that electrically connect the adjacent photovoltaic conversion cells 110 in series, and are films having optical transparency wherein the light that is incident from the glass substrate 101 side penetrates towards the photovoltaic conversion layer 107. The first transparent conductive films 104 are deposited such that they extend across an adjacent pair of photovoltaic conversion cells 110. Mutually adjacent first transparent conductive films 104 are formed such that they have a predetermined spacing. Specifically, as well as one of the first transparent conductive films 104 being deposited within the formation area of a photovoltaic conversion cell 110, one end portion is deposited such that it extends to within the formation area of another adjacent photovoltaic conversion cell 110.

The photovoltaic conversion layer 107 is a layer that converts the light that is incident from the glass substrate 101 side into electrical power. The photovoltaic conversion layer 107 is formed across adjacent first transparent conductive films 104, and the area in which one photovoltaic conversion layer 107 is formed is approximately the same as the area of one photovoltaic conversion cell 110. As the photovoltaic conversion layer 107, those formed from a c-Si layer, a μc-Si (microcrystalline silicon) layer, a CIS type compound layer (a uniform layer comprising a composition of Cu, In, and Se), a CGIS type compound layer (a layer in which Ga has been further added to a uniform layer comprising a composition of Cu, In, and Se), or the like, can be exemplified.

The photovoltaic conversion layer 107 may be a photovoltaic conversion layer representing a tandem construction comprising a multilayered power generation layer structure of a-Si layer, a c-Si layer, a μc-Si layer, and the like, and it is not particularly limited.

The second transparent conductive film 108 is a film that has been deposited with Ga-doped ZnO (GZO) as the material, and is a film that is conductive.

The refractive index adjustment layer 109 is a layer that has been deposited with SiO₂ or MgF₂, which have a lower refractive index than that of GZO, as the material, and is a layer that is conductive.

The back face non-transparent electrode 102 is an electrode formed from Ag, and is electrically connected to the first transparent conductive film 104 of one adjacent photovoltaic conversion cell 110. Furthermore, the back face non-transparent electrode 102, together with the second transparent conductive film 108 and the refractive index adjustment layer 109, reflects the light that is incident from the glass substrate 101 side. On the back face non-transparent electrode 102, in the area facing the first transparent conductive film 104 of the adjacent photovoltaic conversion cell 110, a connection portion 102a that extends towards the first transparent conductive film 104 is formed.

Next the production method of the photovoltaic conversion module 120 is explained.

In regard to the photovoltaic conversion module 120, firstly, the first transparent conductive film 104 is deposited on the entire back face of the glass substrate 101, and as a result of etching, it is processed into the predetermined shapes of the first transparent conductive films 104. Following formation of the first transparent conductive films 104, the photovoltaic conversion layer 107 is deposited on the entire face, and as a result of etching, it is processed into the predetermined shapes of the photovoltaic conversion layers 107. Following formation of the photovoltaic conversion layers 107, the second transparent conductive film 108 is deposited on the entire face, and as a result of etching, it is processed into the predetermined shapes of the second transparent conductive films 108. Following formation of the second transparent conductive films 108, the refractive index adjustment layer 109 is deposited on the entire face, and as a result of etching, it is processed into the predetermined shapes of the refractive index adjustment layers 109. Following formation of the refractive index adjustment layers 109, open holes that form the connection portions 102a, are formed as a result of etching. The back face non-transparent electrode 102 is deposited on the entire face, and as a result of etching, it is processed into the predetermined shapes of the back face non-transparent electrodes 102, and consequently, the photovoltaic conversion module 120 is completed.

The plurality of photovoltaic conversion cells 110 in the photovoltaic conversion module 120 may be in a configuration in which they are connected in series as mentioned above, or they may be a configuration in which multiple groups of photovoltaic conversion cells connected in series are connected in parallel, and this is not particularly limited. These configurations are appropriately determined based on the voltage and the current value demanded from the photovoltaic conversion module 120.

In regard to the photovoltaic conversion module 120, as a result of being furnished with the photovoltaic conversion cell 110 of the present invention, the photovoltaic conversion efficiency can be improved. If the photovoltaic conversion efficiency improves, the photoreceptive area of the photovoltaic conversion module 120 necessary for obtaining the same amount of electrical energy becomes smaller, and as well as reducing the production cost of the photovoltaic conversion module 120, the installation area of the photovoltaic conversion module 120 can be made smaller. Alternatively, more electrical energy can be obtained by the same photoreceptive area.

### Third Embodiment

Hereinbelow, a photovoltaic conversion panel furnished with the photovoltaic conversion module according to a third embodiment of the present invention is explained.

FIG. 17 is a drawing explaining the configuration of the photovoltaic conversion panel according to the present embodiment.

The photovoltaic conversion panel 201 is furnished with, as shown in FIG. 17, the photovoltaic conversion module 120 according to the second embodiment, a coating film 203, a frame body 205, wiring 207, and a terminal box (wiring) 209.

The coating film 203 is a laminate film that protects the face on the back face non-transparent electrode 102 side in the photovoltaic conversion module 120. The frame body 205 covers the surroundings of the photovoltaic conversion module 120, and supports the photovoltaic conversion module 120. The wiring 207 leads the electrical power generated in the photovoltaic conversion module 120 to the terminal box 209. In regard to the wiring 207, one that is electrically connected to the back face non-transparent electrodes 102, and another that is electrically connected to the first transparent conductive films 104, are provided. The terminal box 209 is a connection portion that supplies the electrical power of the photovoltaic conversion module 120 led through the wiring 207 to the outside.

As a DC electrical power voltage supplied by the photovoltaic conversion panel 201 to the outside, 100 V can be exemplified.

In regard to the photovoltaic conversion panel 201, by being furnished with the photovoltaic conversion module 120 of the present invention, the photovoltaic conversion efficiency can be improved. If the photovoltaic conversion efficiency improves, the photoreceptive area of the photovoltaic conversion panel 201 necessary for obtaining the same electrical energy becomes smaller, the production cost of the photovoltaic conversion panel 201 is lower, and the installation area of the photovoltaic conversion panel 201 can be made smaller. Alternatively, more electrical energy can be obtained by the same photoreceptive area.

### Fourth Embodiment

Hereinbelow, a photovoltaic conversion system furnished with the photovoltaic conversion module of the second and the third embodiments according to the present invention is explained.

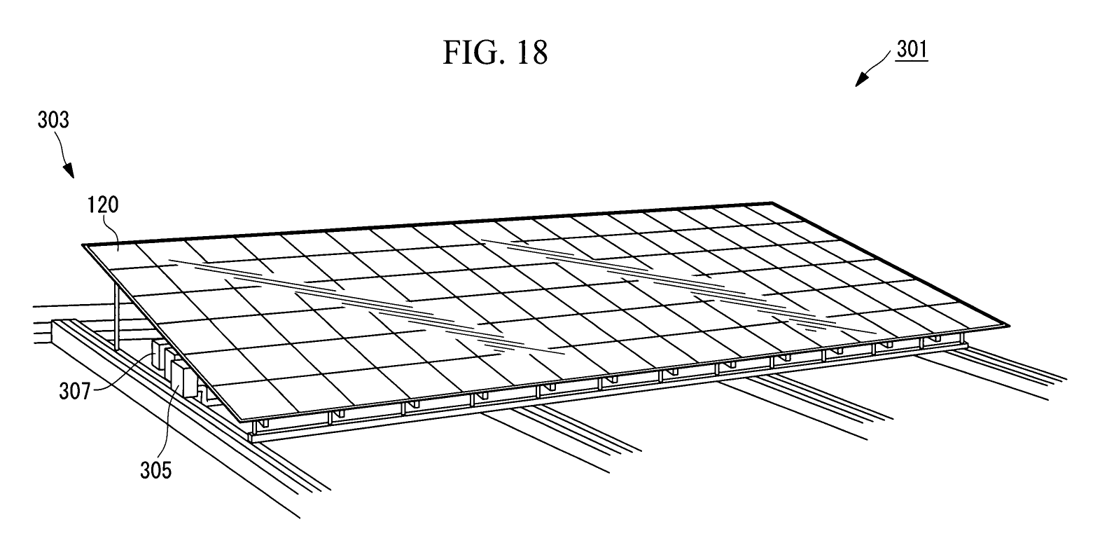

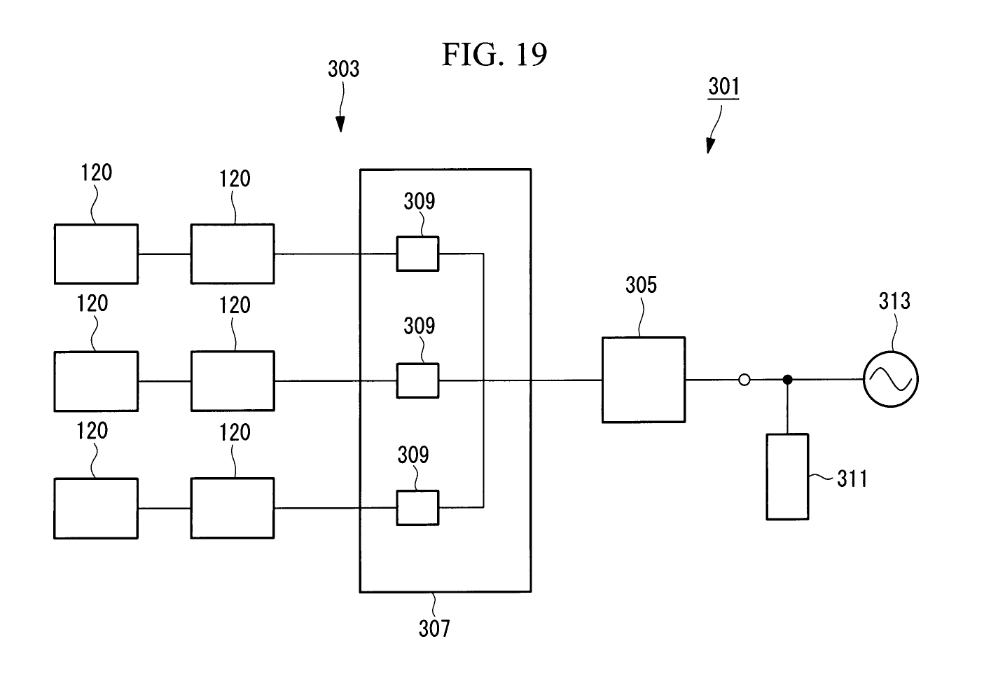

FIG. 18 is a perspective view explaining the external configuration of the photovoltaic conversion system according to the present embodiment. FIG. 19 is a block diagram explaining the configuration of the photovoltaic conversion system of FIG. 18.

The photovoltaic conversion system 301 is, as shown in FIG. 18, furnished with a photovoltaic conversion panel 303 and an inverter 305.

The photovoltaic conversion panel 303 is, as shown in FIG. 19, furnished with a plurality of photovoltaic conversion modules 120 and a terminal box 307.

Since the photovoltaic conversion module 120 is the same as the photovoltaic conversion modules explained in the second and the third embodiments, explanation thereof is omitted. The photovoltaic conversion module 120 configures units of two photovoltaic conversion modules 120 connected in series, and the outputs of the photovoltaic conversion modules 120 of these units are respectively input into the terminal box 307 in parallel. For example, in the case in which one photovoltaic conversion module 120 supplies a DC electrical power of 100 V, a unit of photovoltaic conversion modules 120 supply a DV electrical power of 200 V to the terminal box 307.

The terminal box 307 collects and outputs the output electrical power of the plurality of units of photovoltaic conversion modules 120 to the inverter 305 as one, and the voltage rises to a predetermined DC voltage. A plurality of boost choppers 309 are provided in the terminal box 307, and the electrical power output from the photovoltaic conversion modules 120 is input into the respective boost choppers 309. The output of the boost choppers 309 is collectively input into the inverter 305 as one. The boost chopper 309 performs maximum power point tracking, and converts the output electrical power of the photovoltaic conversion modules 120 into an electrical power having a predetermined DC voltage.

The inverter 305 converts the DC electrical power output from the terminal box 307 into AC electrical power. The AC electrical power converted by the inverter 305 is supplied to the load 311 connected to the photovoltaic conversion system 301. By converting the DC electrical power into AC electrical power as a result of the inverter 305, electrical power can be supplied to the load 311 by a system interconnection with an external electrical power system 313. Alternatively, electrical power can be supplied to the electrical power system 313.

In regard to the photovoltaic conversion system 301, by being furnished with the photovoltaic conversion module 120 of the present invention, the photovoltaic conversion efficiency can be improved. If the photovoltaic conversion efficiency improves, the photoreceptive area of the photovoltaic conversion system 301 necessary for obtaining the same electrical energy becomes smaller, the production cost of the photovoltaic conversion system 301 is lower, and the installation area of the photovoltaic conversion system 301 can be made smaller. Alternatively, more electrical energy can be obtained by the same photoreceptive area.

### Fifth Embodiment

Hereinbelow, a photovoltaic conversion system furnished with the photovoltaic conversion module of the second and the third embodiments according to the present invention is explained.

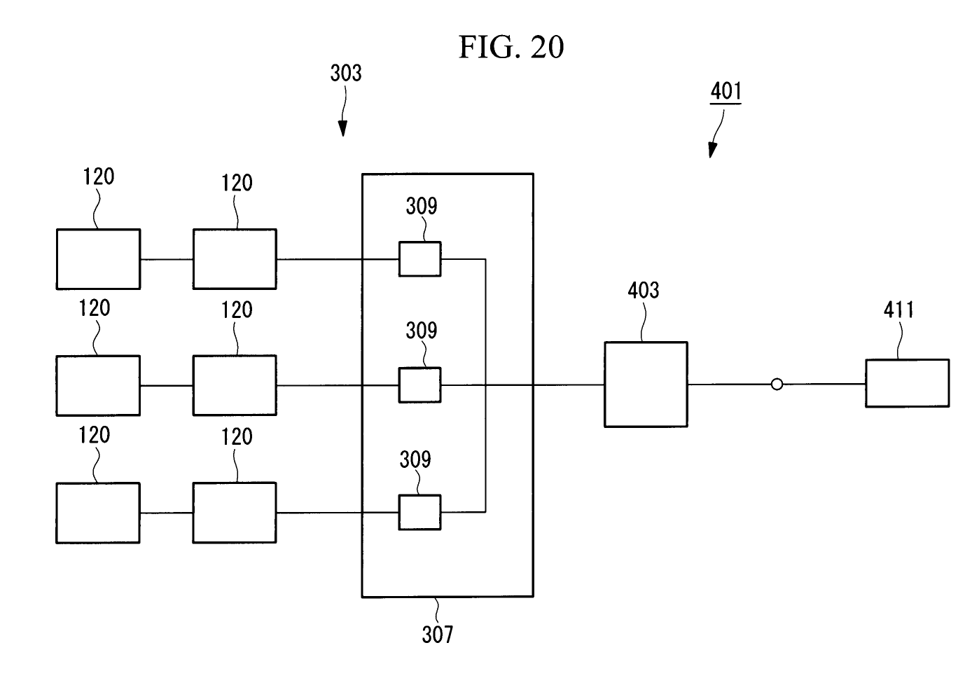

FIG. 20 is a block diagram explaining the configuration of the photovoltaic conversion system according to the present embodiment.

The photovoltaic conversion system 401 is, as shown in FIG. 20, furnished with a photovoltaic conversion panel 303 and a storage battery 403.

The photovoltaic conversion panel 303 is, as shown in FIG. 20, furnished with a plurality of photovoltaic conversion modules 120 and a terminal box 307.

Since the photovoltaic conversion module 120 is the same as the photovoltaic conversion modules explained in the second and the third embodiments, explanation thereof is omitted. Since the terminal box 307 is the same as the terminal box explained in the fourth embodiment, explanation thereof is omitted.

The storage battery 403 temporarily stores the DC electrical power output from the terminal box 307. The DC electrical power temporarily stored in the storage battery 403 is supplied to the load 411 connected to the photovoltaic conversion system 401. As the storage battery 403, one that is commonly known can be used, and this is not particularly limited.

Since the storage battery 403 is provided, the fluctuations in the DC voltage supplied from the photovoltaic conversion system 401 can be controlled.

In regard to the photovoltaic conversion system 401, by being furnished with the photovoltaic conversion module 120 of the present invention, the photovoltaic conversion efficiency can be improved. If the photovoltaic conversion efficiency improves, the photoreceptive area of the photovoltaic conversion system 401 necessary for obtaining the same electrical energy becomes smaller, the production cost of the photovoltaic conversion system 401 is lower, and the installation area of the photovoltaic conversion system 401 can be made smaller. Alternatively, more electrical energy can be obtained by the same photoreceptive area.

What is claimed is:

1. A photovoltaic conversion cell comprising:
a transparent substrate;
a first photovoltaic conversion layer formed on a principal plane side of said transparent substrate that converts received light into electrical power;
a back face electrode layer formed on said principal plane side, and formed at a side of said first photovoltaic conversion layer opposite to a side in which outside light is incident on said first photovoltaic conversion layer; and
a transparent layer which is formed between said first photovoltaic conversion layer and said back face electrode, and for which a side that is closer to said back face electrode layer has a smaller refractive index than a side that is distant from said back face electrode layer.

2. A photovoltaic conversion cell according to claim 1, wherein said transparent layer comprises:
an upper portion transparent layer; and
a refractive index adjustment layer, which is provided between said upper portion transparent layer and said back face electrode layer, and which has a smaller refractive index than that of said upper portion transparent layer.

3. A photovoltaic conversion cell according to claim 2, wherein said upper portion transparent layer contains at least one of ZnO, ITO, and SnO₂, and said ZnO is doped with at least one of Ga, Si, Al, and B.

4. A photovoltaic conversion cell according to claim 2, wherein said refractive index adjustment layer contains at least one of SiO₂, MgF₂, MgO, glass, Al₂O₃, Y₂O₃, CaF₂, LiF, and cavities.

5. A photovoltaic conversion cell according to claim 4, wherein
said refractive index adjustment layer contains a mixed phase between a first material and a second material;
said first material selected from among SiO₂, MgF₂, MgO, glass, Al₂O₃, Y₂O₃, CaF₂, and LiF; and
said second material selected from among ZnO, ITO, and SnO₂, said ZnO doped with at least one of Ga, Si, Al, and B.

6. A photovoltaic conversion cell according to claim 2, wherein said back face electrode layer contains at least one of Ag, Al, Cu, and Au.

7. A photovoltaic conversion cell according to claim 2, wherein a thickness of said refractive index adjustment layer is at least 2 nanometers.

8. A photovoltaic conversion cell according to claim 2, wherein a thickness of said refractive index adjustment layer is from 5 nanometers to 25 nanometers.

9. A photovoltaic conversion cell according to claim 2, wherein a thickness of said refractive index adjustment layer is from 10 nanometers to 20 nanometers.

10. A photovoltaic conversion cell according to claim 1, wherein
said transparent layer has a layer structure of at least three layers, and
a refractive index of an upper side transparent layer, which is one of the layers in said layer structure, is greater than a refractive index of a lower side transparent layer, which is another of the layers between said upper side transparent layer and said back face electrode layer.

11. A photovoltaic conversion cell according to claim 1, wherein
said first photovoltaic conversion layer contains polycrystalline silicon,
and further comprising a second photovoltaic conversion layer containing amorphous silicon at a side opposite to said back face electrode layer with respect to said first photovoltaic conversion layer.

12. A photovoltaic conversion cell according to claim 11, wherein said first photovoltaic conversion layer contains at least one of a compound between silicon and a group IV element other than silicon, a CIS type compound, and a CIGS type compound.

13. A photovoltaic conversion cell according to claim 11, further comprising a third photovoltaic conversion layer containing polycrystalline silicon between said first photovoltaic conversion layer and said second photovoltaic conversion layer.

14. A photovoltaic conversion cell according to claim 13, wherein said third photovoltaic conversion layer contains at least one of a compound between silicon and a group IV element other than silicon, a CIS type compound, and a CIGS type compound.

15. A photovoltaic conversion cell according to claim 1, comprising:
a non-transparent substrate;
a back face electrode layer formed on a principal plane side of said non-transparent substrate;
the first photovoltaic conversion layer formed on said principal plane side and converts received light into electrical power;
a transparent electrode layer which is formed on said principal plane side, and from a side at which incident light is received; and
a transparent layer which is formed between said back face electrode layer formed at a side of said first photovoltaic conversion layer opposite to a side in which outside light is incident on said first photovoltaic conversion layer, and said first photovoltaic conversion layer, and for which a side that is closer to said back face electrode layer has a smaller refractive index than that of the side that is distant from said back face electrode layer.

16. A photovoltaic conversion module wherein a plurality of the photovoltaic conversion cell according to claim 1 is disposed on a substrate, and the photovoltaic conversion cells are electrically connected.

17. A photovoltaic conversion panel comprising:
at least one photovoltaic conversion module according to claim 16; and
wiring that is at least electrically connected with said back face electrode layer and supplies DC electrical power generated in said photovoltaic conversion modules to an external load.

18. A photovoltaic conversion system comprising:
at least one photovoltaic conversion panel according to claim 17; and
an inverter that is electrically connected with said wiring, which converts DC electrical power provided to at least one of an external load and an electrical power system, into AC electrical power.

19. A photovoltaic conversion system comprising:
at least one photovoltaic conversion panel according to claim 17; and
a storage battery that is electrically connected with said wiring, which temporarily stores electrical power supplied to an external load.
